(19) United States
(12) Patent Application Publication
(10) Pub. No.: US 2020/0091266 A1
(43) Pub. Date: Mar. 19, 2020

(54) DISPLAY PANEL AND DISPLAY DEVICE

(71) Applicants: HKC CORPORATION LIMITED, SHUITIAN VILLAGE, SHIYAN SUB-DISTRIC (CN); CHONGQING HKC OPTOELECTRONICS TECHNOLOGY CO.,LTD., CHONGQING (CN)

(72) Inventor: EN-TSUNG CHO, CHONGQING (CN)

(21) Appl. No.: 16/500,543

(22) PCT Filed: Aug. 10, 2017
(86) PCT No.: PCT/CN2017/096716

§ 371 Date: Oct. 3, 2019

(30) Foreign Application Priority Data
Apr. 7, 2017 (CN) 201710223656.3

(51) Int. Cl. H01L 27/32; H01L 51/00

(52) U.S. Cl. CPC H01L 27/3272; H01L 27/322; H01L 27/3258; H01L 27/1225; H01L 51/0097; H01L 2251/5338; H01L 27/3262

(57) ABSTRACT

A display panel includes a substrate, active switches disposed on the substrate, a color filter layer disposed on the substrate, and a passivation layer disposed on the substrate, wherein the passivation layer covers the substrate, the active switches, and the color filter layer.

### CROSS-REFERENCE TO RELATED APPLICATION

This application claims priority from CN Application No. 201710223656.3 filed on Apr. 7, 2017, in SIPO, the content of which is hereby incorporated by reference in their entirety for all purposes.

### BACKGROUND

### 1. Field

The present disclosure relates to display panel technology, especially relates to a display panel and a display device.

### 2. Description of the Related Art

An active-matrix organic light emitting diode (AMOLED) display is characterized by its high contrast ratios, wide color gamut, and short response time. As an AMOLED generates light without the need of a backlight plate, it can be made with less weight and higher flexibility than an AMLCD. The AMOLED display panel adopts a particular TFT to control OLED's on-and-off and to adjust its brightness, whereby the image is then displayed after the adjustment of proportions of three primary colors. Wherein, the control TFT usually employs metal oxide semiconductors, which not only have higher on-state current and lower off-state current but also represent better uniformity and stability.

In the color filter on array (COA) panel technique, the formation of RGB is followed by more complicated procedures, which usually have influence on the organic materials of RGB, resulting in the damage of OLED components and impact on the display lifetime and performance.

### SUMMARY

In one aspect of the present disclosure, a display panel is provided, which includes a substrate, active switches, a color filter layer, a passivation layer, a buffer layer, an interlayer dielectric layer and a light shading layer. The active switches are disposed on the substrate. The color filter layer is disposed on the substrate. The passivation layer is disposed on the substrate, wherein the passivation layer covers the substrate, the active switches, and the color filter layer. The buffer layer is disposed to cover the substrate. The interlayer dielectric layer is disposed between the buffer layer and the passivation layer, wherein the color filter layer is disposed on the interlayer dielectric layer and the color filter layer is disposed separately from the active switches. The active switch comprises a semiconductor layer, a source electrode, and a drain electrode. The source electrode and the drain electrode are respectively connected to two ends of the semiconductor layer. The semiconductor layer is disposed between the buffer layer and the interlayer dielectric layer. One end of each one of the source electrode and the drain electrode is disposed between the passivation layer and the interlayer dielectric layer, and the other end of each one of the source electrode and the drain electrode extends through the interlayer dielectric layer and connects the semiconductor layer. The light shading layer is disposed on the substrate and between the buffer layer and the substrate. The source electrode extends through the buffer layer and connects the light shading layer. The light shading layer is disposed between orthographic projecting positions of the source electrode and the drain electrode on the substrate. The light shading layer fills an interval between the orthographic projecting positions of the source electrode and the drain electrode on the substrate.

In one other aspect of the present disclosure, a display panel is provided, which includes a substrate, active switches, a color filter layer and a passivation layer. The active switches, color filter layer and passivation layer are all disposed on the substrate. The passivation layer covers the substrate, the active switches and the color filter layer.

In another aspect of the present disclosure, a display device is provided. The display device comprises a display panel. The display panel includes a substrate, active switches, a color filter layer and a passivation layer. The active switches, color filter layer and passivation layer are all disposed on the substrate. The passivation layer covers the substrate, the active switches and the color filter layer.

### BRIEF DESCRIPTION OF THE DRAWINGS

FIG. 1 is a schematic diagram showing a cross section of a display panel in an embodiment;

FIG. 2 is a schematic diagram showing a cross section of a display panel in another embodiment;

FIG. 3 is a schematic diagram showing a cross section of a display panel in another embodiment;

FIG. 4 is a schematic diagram showing a cross section of a display panel in another embodiment;

FIG. 5 is a schematic diagram showing a cross section of a display panel in another embodiment;

FIG. 6 is a schematic diagram showing a cross section of a display panel in another embodiment.

### DESCRIPTION OF THE PREFERRED EMBODIMENTS

The specific structures and functional details disclosed herein are only representative, and the purpose thereof is to illustrate the exemplary embodiments of the present disclosure. The present disclosure, however, may be embodied in many alternative forms and should not be construed as being limited to the embodiments set forth herein.

In the description of the present disclosure, it is understood that the indicative direction or positional relationship terms such as “center”, “horizontal”, “upper”, “lower”, “left”, “right”, “vertical”, “level”, “top”, “bottom”, “inside”, “outside”, etc. are based on the positions or positional relationship shown in the drawings. The purpose is solely to facilitate the description of the present disclosure and to simplify description, but not to indicate or to imply that the devices or elements are limited to specific directions or positions, or constructed or operated in specific orientations, these terms cannot be construed as limiting the present disclosure. In addition, the terms “first”, “second”, etc. are for illustrative purposes only and are not to be construed as indicating or implying a relative importance or implying or indicating the number of technical features. For the technical features described by “first”, “second”, etc. They should be construed as expressly or implicitly including one or more of such features. In the description of the present disclosure, “many” or “a plurality of” is to indicate two or more unless otherwise defined. In addition, the term “include” and any variants thereof are intended to mean non-exclusive inclusion.

In the description of the present disclosure, it should be noted that, unless specified or limited otherwise, the terms “mounted”, “connected”, or “coupled” should be considered as general terms including the meanings such as fixedly coupled, detachably coupled, formed as a single element, mechanical or electrical couplings, inner couplings of two components, direct couplings, or indirect couplings through intermediaries. A person in the art with ordinary skill can understand the meanings of the aforementioned terms in the present disclosure based on particular situations.

The terms used herein are solely to illustrate but not to limit the exemplary embodiments. Unless specifically specified in the context, the singular forms “a” and “an” are intended to include the plural forms. It should also be understood that the terms “include(s)/including” and/or “comprise(s)/comprising” used herein is to specify the presence of stated features, integers, steps, operations, elements, and/or components, but not to preclude the presence or addition of one or more other features, integers, steps, operations, elements, components, and/or combinations thereof.

Accompanying with the corresponding figures, the following will illustrate the preferred embodiments of the present disclosure.

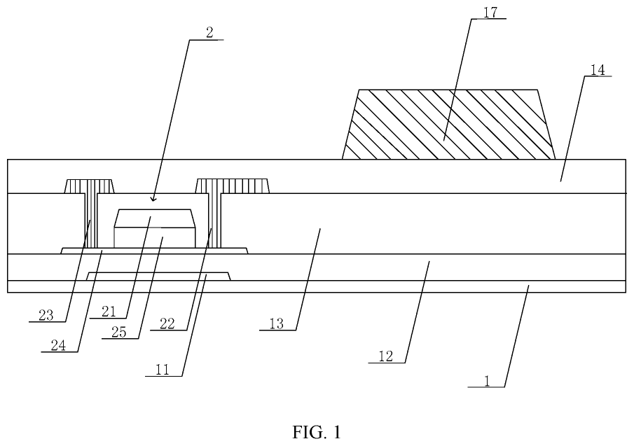

As shown in FIG. 1, the applicant(s) designs a display panel that is not disclosed before, which includes a substrate 1, an active switch 2, and a color filter layer 17. Wherein, a buffer layer 12 and a passivation layer 14 are disposed on and cover the substrate 1, and an interlayer dielectric layer 13 is disposed between the buffer layer 12 and the passivation layer 14. A light shading layer 11 is disposed between the buffer layer 12 and the substrate 1, and the color filter layer 17 is disposed on the upper surface of the passivation layer 14. The active switch 2 is disposed on the lower surface of the passivation layer 14, and a planarization layer 15 and an emission layer 16 is disposed on and cover the color filter layer 17. The emission layer 16 includes a white organic light-emitting diode 161 or WOLED. For the AMOLED process using evaporation as a main approach, in order to lower the processing threshold and to reduce degradation and non-uniformity of luminance and chromaticity of the emissive materials, the display usually uses the color filter layer 17 together with the white organic light-emitting diode 161 as an approach. In the traditional COA technique, after the formation of the active switch 2, the coating of the passivation layer 14 is performed to protect the active switch 2, and the color filter layer 17 of the display panel is then applied (RGB procedure). Finally, the RGB follow-up procedures such as the coating of the planarization layer 15, the arrangement of the emission layer 16, etc. are executed. After completion of the RGB procedure, there are still more complicated procedures requiring highly sophisticated operations, which tend to damage the structure formed by the RGB procedure. The display panel cannot be effectively protected.

The studies conducted by the applicant(s) further disclose that these more complicated procedures following the RGB procedure cause the organic materials, which are main materials of the color filter layer 17 in the RGB procedure, to release some harmful impurity gases that damage the display panel, thereby impacting the display lifetime and performance. Therefore, the applicant(s) provides an innovative technique to effectively prevent the display panel from being damaged and a display panel with improved lifetime and performance.

The following refers to the drawings, which illustrate schematic diagrams of structures of display panels in the embodiments.

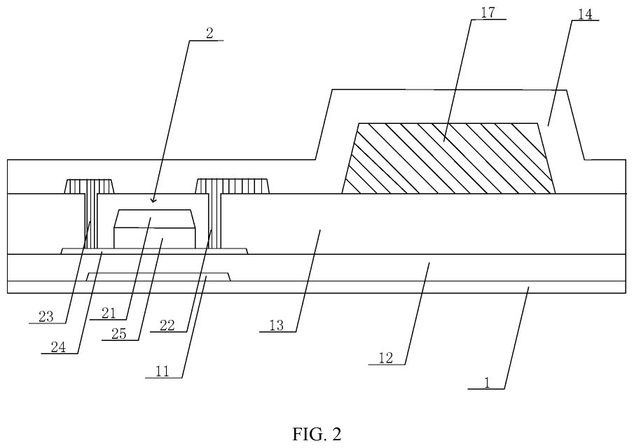

As shown in FIG. 2, the display panel includes a substrate 1, an active switch 2, and a color filter layer 17, and a passivation layer 14 disposed on the substrate and covering the substrate 1, the active switch 2, and the color filter layer 17.

By covering the passivation layer 14 on the active switch 2 and the color filter layer 17, the gas releasing issue of the color filter layer 17 during the color filter follow-up procedures can be well prevented, and the color filter layer 17 can be well protected by the passivation layer 14, thereby securing the lifetime and performance of the display panel without adding processing step and changing current masks. Solely the change of the mask processing sequence can bring about an effective protection to the display panel and a better display panel performance, thereby further improving the display effect of the display panel.

A buffer layer 12 is disposed on and covers the substrate 1, and an interlayer dielectric layer 13 is disposed between the buffer layer 12 and the passivation layer 14. The color filter layer 17 is disposed on the interlayer dielectric layer 13, and the color filter layer 17 is disposed separately from the active switch 2. Wherein, the active switch 2 has an excellent light shading effect that alleviates the display non-uniformity or color blending occurrence, thereby providing the display panel with a better display performance. The separation between the color filter layer 17 and the active switch 2 offers an excellent pixel definition of the display panel, thereby providing a better control and adjustment of the performance of the display panel.

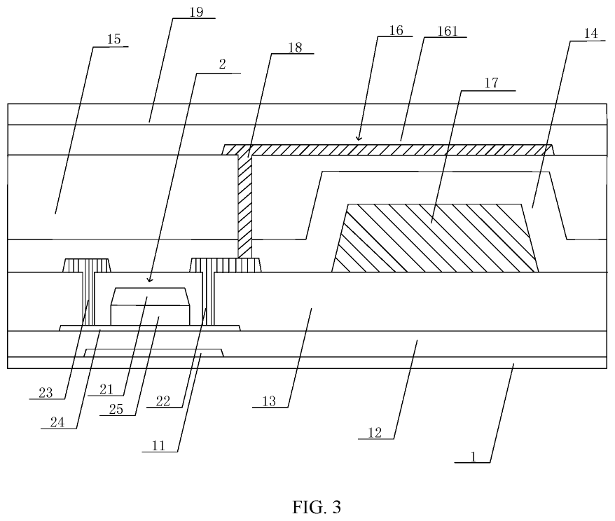

As shown in FIG. 3, a planarization layer 15 and an emission layer 16 are disposed on the passivation layer 14. The planarization layer 15 is disposed between the passivation layer 14 and the emission layer 16, and a transparent anode 18 is disposed on the lower surface of the emission layer 16, which means the transparent anode 18 is disposed between the emission layer 16 and the planarization layer 15. Wherein, the material of the transparent anode can be chosen from a variety of transparent conductive materials such as graphene composites, indium tin oxide (ITO), or a like. A metal cathode 19 is disposed on the upper surface of the emission layer 16. The emission layer 16 is provided with a white organic light-emitting diode 161, and the white organic light-emitting diode 161 and the color filter layer 17 are disposed correspondingly to each other. Wherein, the white organic light-emitting diode 161 has greater orthographic projection area on the substrate 1 than the color filter layer 17 does. The orthographic projection area of the white organic light-emitting diode 161 on the substrate 1 fully covers the orthographic projection area of the color filter layer 17, such that the light emitted from the white organic light-emitting diode 161 can well pass through the color filter layer 17, thereby notably improving the performance of the display panel.

The active switch 2 includes a semiconductor layer 24, a source electrode 22, and a drain electrode 23. The source electrode 22 and the drain electrode 23 connect each one of two ends of the semiconductor layer, respectively. The semiconductor layer 24 is disposed between the buffer layer 12 and the interlayer dielectric layer 13. One end of each one of the source electrode 22 and the drain electrode 23 is disposed between the passivation layer 14 and the interlayer dielectric layer 13, and the other end of each one of the source electrode 22 and the drain electrode 23 extends through the interlayer dielectric layer 13 and connects the semiconductor layer 24. The active switch 2 further includes a gate electrode 21 disposed inside the interlayer dielectric layer 13 and a gate-electrode isolation layer 25 disposed between the gate electrode 21 and the semiconductor layer 24. The gate electrode 21 with its position disposed between the source electrode 22 and the drain electrode 23 also well contributes to the light shading effect.

The semiconductor layer 24 is an oxide thin film layer selected from the group consisting of ZnO, Zn—Sn—O, In—Zn—O, MgZnO, In—Ga—O, In₂O₃, etc., which can be prepared by the method of magnetron sputtering, pulsed laser deposition, electron beam evaporation, or a like. Comparing with the amorphous silicon having lower carrier mobility and strong light sensitivity issues, the oxide thin film layer has higher carrier mobility and distinct advantages regarding to uniformity and stability, thereby showing great potential of its application. The active switch 2 adopting the oxide thin film layer has a higher ON/OFF current flow ratio and higher field-effect mobility, and a high response rate, and is able to achieve larger driving current for manufacturing large area display panels. Also, the active switch 2 adopting the oxide thin film layer can be formed under room temperature, low temperature as such allows for the use of flexible substrates, thereby resulting to the advent of flexible displays, the technology of which bears a higher portability, greater lightness, and better ruggedness. The oxide semiconductors are very suitable semiconductor materials for flexible displays.

Optionally, the oxide thin film layer is an indium-gallium-zinc-oxide thin film layer, the use of which may effectively lower the power consumption of the display panel, thereby contributing to a better energy conservation and being very environmentally friendly. Moreover, the carrier mobility is 20 to 30 times greater than amorphous silicon, which greatly raises the charge and discharge rate of the active switch to pixel electrodes, thereby improving pixel response time and achieving higher refresh rate. The faster response also leads to a much higher pixel line scanning rate, which brings the Pixel Per Inch to a level of full HD or even Ultra Definition. In addition, because of decreased number of transistors and higher transmittance of each pixel, the display panel has higher energy efficient level and even better efficacy. Meanwhile, the amorphous silicon production line can be reused with little modification. Therefore, the cost is more competitive than the use of low temperature polysilicon.

A light shading layer 11 is disposed on the substrate 1. Wherein, the light shading layer 11 can well block the light from the emission layer 16 to effectively prevent the light leakage of the display panel, thereby improving the performance of the display panel. The light shading layer 11 is disposed and fills the interval between the orthographic projecting positions of the source electrode 22 and the drain electrode 23 on the surface of the substrate 1, such that the source electrode 22 and drain electrode 23 effectively block the light from the emission layer 16 projected on the source electrode 22 and drain electrode 23. The gate electrode 21 can well block the light projected on the position between the source electrode 22 and drain electrode 23. For the light not being blocked by the gate electrode 21 on this position, the light shading layer fills the interval between the orthographic projecting positions of the source electrode 22 and the drain electrode 23 on the substrate 1. It can effectively block the light from the emission layer 16 projected to prevent the light from the emission layer 16 leaking through the active switch 2, which alleviates display non-uniformity and color blending occurrence, thereby achieving better performance of the display panel and, therefore, further improving display effect of the display panel. Certainly, there can be no light shading layer 11 at the orthographic projecting position of the gate electrode 21 on the substrate 1, which can effectively save material consumption to well reduce the production cost of the display panel, and can effectively lower the weight of the display panel, thereby providing the display panel with a higher portability.

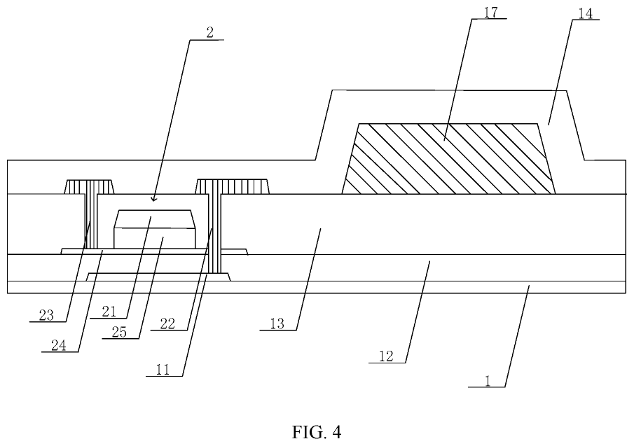

As shown in FIG. 4, the display panel disclosed in this embodiment includes: a substrate 1, an active switch 2, and a color filter layer 17. A passivation layer 14 is disposed on the substrate 1 and covers the substrate 1, the active switch 2, and the color filter layer 17. By covering the passivation layer 14 on the active switch 2 and the color filter layer 17, the gas-releasing issue of the color filter layer 17 during the color filter follow-up procedures can be well prevented. The color filter layer 17 can be well protected by the passivation layer 14, thereby securing the lifetime and performance of the display panel without adding processing step and changing current mask types, and solely the change of the mask processing sequence can bring about an effective protection to the display panel.

A buffer layer 12 is disposed on and covers the substrate 1, and an interlayer dielectric layer 13 is disposed between the buffer layer 12 and the passivation layer 14. The color filter layer is disposed on the interlayer dielectric layer 13, and the color filter layer 17 is disposed separately from the active switch 2. Wherein, the active switch 2 has an excellent light shading effect that alleviates the display non-uniformity or color blending occurrence, thereby providing the display panel with a better display performance. The separation between the color filter layer 17 and the active switch 2 offers an excellent pixel definition of the display panel, thereby providing a better control and adjustment of the performance of the display panel.

A light shading layer 11 is disposed on the substrate 1 and can well block the light from the emission layer 16 to prevent the light leakage of the display panel, thereby improving the performance of the display panel. The light shading layer 11 is disposed between the buffer layer 12 and the substrate 1. The source electrode 22 extends through the buffer layer 12 and connects the light shading layer 11 to effectively block the light from the emission layer 16. Therefore, efficiently prevents the light from the emission layer 16 being leaked through the active switch 2, which effectively alleviates display non-uniformity and color blending occurrence, thereby achieving better performance of the display panel and, therefore, further improving display effect of the display panel.

The light shading layer 11 is disposed and fills the interval between the orthographic projecting positions of the source electrode 22 and the drain electrode 23 on the surface of the substrate 1, such that the source electrode 22 and drain electrode 23 effectively block the light projected on the source electrode 22 and drain electrode 23 from the emission layer 16. The gate electrode 21 can well block the light projected on the position between the source electrode 22 and drain electrode 23. For the light not being blocked by the gate electrode 21 on this position, the light shading layer fills the interval between the orthographic projecting positions of the source electrode 22 and the drain electrode 23 on the surface of the substrate 1. It can effectively block the light from the emission layer 16 projected on it to prevent the light from the emission layer 16 being leaked through the active switch 2, which effectively alleviates display non-uniformity and color blending occurrence, thereby achieving better performance of the display panel and, therefore, further improving display effect of the display panel. Certainly, there can be no light shading layer 11 at the orthographic projecting position of the gate electrode on the substrate 1, which can effectively save material consumption to well reduce the production cost of the display panel, and can effectively lower the weight of the display panel, thereby providing the display panel with a higher portability.

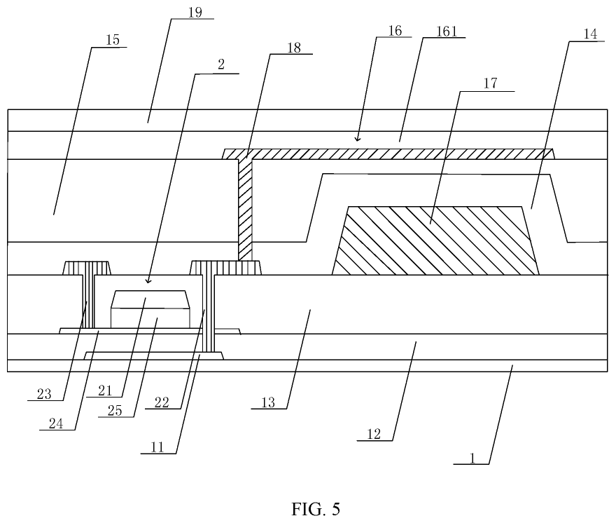

As shown in FIG. 5, a planarization layer 15 and an emission layer 16 are disposed on the passivation layer 14. The planarization layer 15 is disposed between the passivation layer 14 and the emission layer 16. A transparent anode 18 is disposed on the lower surface of the emission layer 16, which means the transparent anode 18 is disposed between the emission layer 16 and the planarization layer 15. A metal cathode 19 is disposed on the upper surface of the emission layer 16. The emission layer 16 is provided with a white organic light-emitting diode 161, and the white organic light-emitting diode 161 and the color filter layer 17 are disposed correspondingly to each other. Wherein, the white organic light-emitting diode 161 has a greater orthographic projection area on the substrate 1 than the color filter layer 17 does. The projection area of the white organic light-emitting diode 161 on the substrate 1 can fully cover the orthographic projection area of the color filter layer 17 on the substrate 1. Thus, the light emitted from the white organic light-emitting diode 161 can well pass through the color filter layer 17, thereby notably improving the display performance of the display panel.

The active switch 2 includes a semiconductor layer 24, a source electrode 22, and a drain electrode 23. The source electrode 22 and the drain electrode 23 connect each one of two ends of the semiconductor layer 24 respectively. The semiconductor layer 24 is disposed between the buffer layer 12 and the interlayer dielectric layer 13. One end of each one of the source electrode 22 and the drain electrode 23 is disposed between the passivation layer 14 and the interlayer dielectric layer 13, and the other end of each one of the source electrode 22 and the drain electrode 23 extends through the interlayer dielectric layer 13 and connects the semiconductor layer 24. The active switch 2 further includes a gate electrode 21 disposed inside the interlayer dielectric layer 13 and a gate-electrode isolation layer 25 disposed between the gate electrode 21 and the semiconductor layer 24. The gate electrode 21 with its position located between the source electrode 22 and the drain electrode 23 also well contributes to the light shading effect.

The semiconductor layer 24 is an oxide thin film layer selected from the group consisting of ZnO, Zn—Sn—O, In—Zn—O, MgZnO, In—Ga—O, In₂O₃, etc., which can be prepared by the method of magnetron sputtering, pulsed laser deposition, electron beam evaporation, or a like. Comparing with the amorphous silicon having lower carrier mobility and strong light sensitivity issues, the oxide thin film layer has higher carrier mobility and distinct advantages regarding to uniformity and stability, thereby showing great potential of its application. The active switch 2 adopting the oxide thin film layer has higher ON/OFF current ratio and higher field-effect mobility, and high response rate, and is able to achieve larger driving current for manufacturing large area display panels. Also, the active switch 2 adopting the oxide thin film layer can be formed under room temperature, low temperature as such allows for the use of flexible substrates, thereby resulting to the advent of flexible displays, the technology of which bears a higher portability, greater lightness, and better ruggedness. The oxide semiconductors are the most suitable semiconductor materials for flexible displays.

Optionally, the oxide thin film layer is an indium-gallium-zinc-oxide thin film layer, the use of which may effectively lower the power consumption of the display panel, thereby contributing to a better energy conservation and being very environmentally friendly. Moreover, the carrier mobility is 20 to 30 times greater than amorphous silicon. The charge and discharge rate of the active switch to pixel electrodes are greatly raises, thereby improving pixel response time and achieving higher refresh rate, and the faster response also leads to a much higher pixel line scanning rate, which brings the Pixel Per Inch to a level of full HD or even Ultra Definition. In addition, because of decreased number of transistors and higher transmittance of each pixel, the display panel has higher energy efficient level and even better efficacy. Meanwhile, the amorphous silicon production line can be reused with little modification. Therefore, the cost is more competitive than the use of low temperature polysilicon.

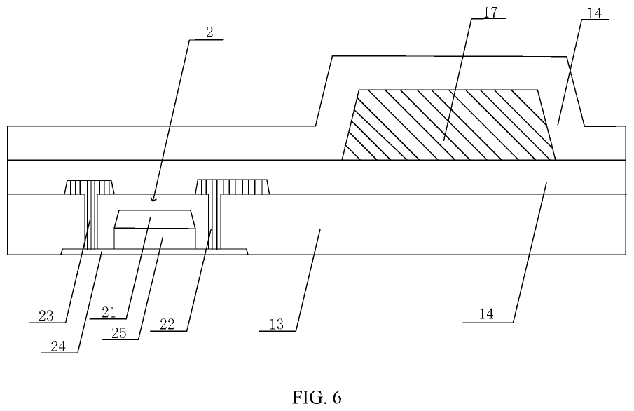

As shown in FIG. 6, the present embodiment modifies the passivation layer 14 into two layers. Wherein, the passivation layers 14 are disposed between the planarization layer 15 and the interlayer dielectric layer 13. The color filter layer 17 is disposed between two passivation layers 14. The microstructure of metal-made source electrode 22 or the drain electrode 23 shows metal burr occurrence on their sides. By arranging two passivation layers 14, the metal burrs on the source electrode 22 and drain electrode 23 can be better covered to effectively prevent the metal burrs' exposure outside the protection layer. Thus, the protection layer can better protect the source electrode 22 and the drain electrode 23 to avoid the influence from the follow-up procedures on the source electrode 22 and the drain electrode 23, thereby well improving the yield of the display panel. The arrangement of the color filter layer 17 between two passivation layers 14 can well protect the color filter layer 17 to avoid the follow-up procedures causing harmful impurity gases released from the organic material of the color filter layer 17, thereby realizing an effective protection of the display panel and increasing its efficiency and prolonging its lift time.

In another aspect of the present disclosure, the present disclosure also discloses a display device, including aforementioned display panel. Wherein, the specific structure and associated connections can refer to FIGS. 1-6 and are not repeated again.

The content above further details the present disclosure accompanying with preferred embodiments, but the embodiments of the present disclosure are not construed as limited to the description. For those skilled in the art, any technical feature that can be obtained by simple logical analysis and inference or replacement based on the present disclosure should be within the scope of the appended claims.

1. A display panel, comprising:
a substrate;
active switches disposed on the substrate;
a color filter layer disposed on the substrate;
a passivation layer disposed on the substrate, wherein the passivation layer covers the substrate, the active switches, and the color filter layer;
a buffer layer disposed to cover the substrate,
an interlayer dielectric layer disposed between the buffer layer and the passivation layer, wherein the color filter layer is disposed on the interlayer dielectric layer and the color filter layer is disposed separately from the active switches;
wherein the active switch comprises a semiconductor layer, a source electrode, and a drain electrode; the source electrode and the drain electrode respectively connect two ends of the semiconductor layer and the semiconductor layer is disposed between the buffer layer and the interlayer dielectric layer, and one end of each one of the source electrode and the drain electrode is disposed between the passivation layer and the interlayer dielectric layer, and the other end of each one of the source electrode and the drain electrode extends through the interlayer dielectric layer and connects the semiconductor layer; and
a light shading layer disposed on the substrate and between the buffer layer and the substrate, wherein the source electrode extends through the buffer layer and connects the light shading layer, and the light shading layer is disposed between orthographic projecting positions of the source electrode and the drain electrode on the substrate, and the light shading layer fills an interval between the orthographic projecting positions of the source electrode and the drain electrode on the substrate.

2. A display panel, comprising:
a substrate;
active switches disposed on the substrate;
a color filter layer disposed on the substrate;
a passivation layer disposed on the substrate, wherein the passivation layer covers the substrate, the active switches and the color filter layer.

3. The display panel of claim 2, wherein a buffer layer is disposed to cover the substrate, and an interlayer dielectric layer is disposed between the buffer layer and the passivation layer, and the color filter layer is disposed on the interlayer dielectric layer and the color filter layer is disposed separately from the active switches.

4. The display panel of claim 3, wherein a planarization layer and an emission layer are disposed on the passivation layer, and the planarization layer is disposed between the passivation layer and the emission layer, and the emission layer is provided with a white organic light-emitting diode, and the white organic light-emitting diode and the color filter layer are disposed correspondingly to each other.

5. The display panel of claim 3, wherein the active switch comprises a semiconductor layer, a source electrode, and a drain electrode, in which the source electrode and the drain electrode connect each one of two ends of the semiconductor layer respectively, and the semiconductor layer is disposed between the buffer layer and the interlayer dielectric layer, and one end of each one of the source electrode and the drain electrode is disposed between the passivation layer and the interlayer dielectric layer, and the other end of each one of the source electrode and the drain electrode extends through the interlayer dielectric layer and connects the semiconductor layer.

6. The display panel of claim 5, wherein the active switch comprises a gate electrode disposed inside the interlayer dielectric layer and a gate-electrode isolation layer disposed between the gate electrode and the semiconductor layer.

7. The display panel of claim 5, wherein the semiconductor layer is an indium-gallium-zinc-oxide thin film layer.

8. The display panel of claim 5, wherein a light shading layer is disposed on the substrate and between the buffer layer and the substrate, and the source electrode extends through the buffer layer and connects the light shading layer.

9. The display panel of claim 8, wherein the light shading layer is disposed between orthographic projecting positions of the source electrode and the drain electrode on the substrate, and the light shading layer fills an interval between the orthographic projecting positions of the source electrode and the drain electrode on the substrate.

10. The display panel of claim 4, wherein there are two passivation layers, which are disposed between the planarization layer and the interlayer dielectric layer, and the color filter layer is disposed between the two passivation layers.

11. A display device, comprising the display device comprises a display panel, wherein the display panel comprises:
a substrate;
active switches disposed on the substrate;
a color filter layer disposed on the substrate;
a passivation layer disposed on the substrate, wherein the passivation layer covers the substrate, the active switches and the color filter layer.

12. The display device of claim 11, wherein a buffer layer is disposed to cover the substrate, and an interlayer dielectric layer is disposed between the buffer layer and the passivation layer, and the color filter layer is disposed on the interlayer dielectric layer and the color filter layer is disposed separately from the active switches.

13. The display device of claim 12, wherein a planarization layer and an emission layer are disposed on the passivation layer, and the planarization layer is disposed between the passivation layer and the emission layer, and the emission layer is provided with a white organic light-emitting diode, and the white organic light-emitting diode and the color filter layer are disposed correspondingly to each other.

14. The display device of claim 12, wherein the active switch comprises a semiconductor layer, a source electrode, and a drain electrode, in which the source electrode and the drain electrode connect each one of two ends of the semiconductor layer respectively, and the semiconductor layer is disposed between the buffer layer and the interlayer dielectric layer, and one end of each one of the source electrode and the drain electrode is disposed between the passivation layer and the interlayer dielectric layer, and the other end of each one of the source electrode and the drain electrode extends through the interlayer dielectric layer and connects the semiconductor layer.

15. The display device of claim 14, wherein the active switch comprises a gate electrode disposed inside the interlayer dielectric layer and a gate-electrode isolation layer disposed between the gate electrode and the semiconductor layer.

16. The display device of claim 14, wherein the semiconductor layer is an oxide thin film layer.

17. The display device of claim 16, wherein the oxide thin film layer is an indium-gallium-zinc-oxide thin film layer.

18. The display device of claim 14, wherein a light shading layer is disposed on the substrate and between the buffer layer and the substrate, and the source electrode extends through the buffer layer and connects the light shading layer.

19. The display device of claim 18, wherein the light shading layer is disposed between orthographic projecting positions of the source electrode and the drain electrode on the substrate, and the light shading layer fills an interval between the orthographic projecting positions of the source electrode and the drain electrode on the substrate.

20. The display device of claim 13, wherein there are two passivation layers, which are disposed between the planarization layer and the interlayer dielectric layer, and the color filter layer is disposed between the two passivation layers.
